(19) United States
(12) Patent Application Publication
(10) Pub. No.: US 2023/0420433 A1
(43) Pub. Date: Dec. 28, 2023

(54) Element Mounting Means, Electrode Means Manufacturing Method, and Smoke Detector Manufacturing Method

(71) Applicant: Hochiki Corporation, Tokyo (JP)

(72) Inventor: Kiyotaka Teshima, Tokyo (JP)

(21) Appl. No.: 18/241,444

(22) Filed: Sep. 1, 2023

Related U.S. Application Data
(63) Continuation-in-part of application No. PCT/JP2021/012127, filed on Mar. 24, 2021.

(51) Int. Cl. H01L 25/16; H01L 31/02; H01L 33/62; G01N 21/53

(52) U.S. Cl. CPC H01L 25/167; H01L 31/02005; H01L 33/62; G01N 21/53; H05K 1/18

(57) ABSTRACT

An element placement unit for placing a light emitting unit and a light receiving unit of a smoke detector that detects smoke by receiving scattered light caused by a scattering of light from the light emitting unit by the smoke, using the light receiving unit, includes: a light emission-side electrode portion having conductivity for placing the light emitting unit while electrically connecting the light emitting unit; and a light reception-side electrode portion having conductivity for placing the light receiving unit while electrically connecting the light receiving unit.

### CROSS REFERENCE TO RELATED APPLICATIONS

The present application claims the benefit of the PCT application No. PCT/JP2021/012127 filed on Mar. 24, 2021 the disclosure of which is incorporated by reference its entirety.

### INCORPORATION BY REFERENCE

All publications and patent applications mentioned in this specification are herein incorporated by reference in their entirety to the same extent as if each individual publication or patent application was specifically and individually indicated to be incorporated by reference.

### TECHNICAL FIELD

The present invention relates to an element placement unit, a method for manufacturing an electrode portion, and a method for manufacturing a smoke detector.

### BACKGROUND ART

In the related art, a smoke detector has been known that detects smoke in a smoke detection space by receiving scattered light caused by the scattering of light from a light emitting element by the smoke, using a light receiving element (for example, refer to PTL 1).

### CITATION LIST

### Patent Literature

Patent Literature 1: Laid-Open Patent Publication in Japan No. 2011-248547

### SUMMARY OF INVENTION

### Technical Problem

By the way, in the smoke detector of the related art, since the light emitting element and the light receiving element are directly attached to a smoke detection unit body for partitioning a part of the smoke detection space inside the smoke detector, it is necessary to accurately attach each element to a relatively narrow portion for attaching each element (for example, a recess or the like for attaching each element) in the smoke detection unit body, which may be time and labor consuming. Therefore, there has been a demand for a technique for easily attaching the light emitting element and the light receiving element.

It is an object of the present invention to solve the problems of the above mentioned prior arts.

### Solution to Problem

One aspect of the present invention provides an element placement unit for placing a light emitting element and a light receiving element of a smoke detector that detects smoke by receiving scattered light caused by a scattering of light from the light emitting element by the smoke, using the light receiving element, the unit comprises: a light emitting element-side electrode portion having conductivity for placing the light emitting element while electrically connecting the light emitting element; and a light receiving element-side electrode portion having conductivity for placing the light receiving element while electrically connecting the light receiving element, wherein the light emitting element-side electrode portion and the light receiving element-side electrode portion are integrally formed on a common frame body.

### BRIEF DESCRIPTION OF DRAWINGS

FIG. 1 is a view for describing an installation state of a detector.

FIG. 2 is an exploded perspective view of some components of the detector.

FIG. 3 is a perspective view of a smoke detection unit body.

FIG. 4 is a perspective view of the smoke detection unit body.

FIG. 5 is a perspective view of an element placement unit.

FIG. 6 is a perspective view of the element placement unit.

FIG. 7A is a front view of the element placement unit.

FIG. 7B is a front view of the element placement unit.

FIG. 7C is a front view of the element placement unit.

FIG. 8 is a plan view of the element placement unit.

FIG. 9 is a rear view of the element placement unit.

FIG. 10 is a bottom view of the element placement unit.

FIG. 11 is a right side view of the element placement unit.

FIG. 12 is a left side view of the element placement unit.

FIG. 13 is a plan view of a plurality of lead frames.

FIG. 14 is a plan view of one lead frame.

FIG. 15 is a partial enlarged view of FIG. 14.

FIG. 16 is a partial enlarged view of FIG. 14.

FIG. 17 is a plan view showing a lead frame with a holding member and the like formed thereon.

FIG. 18 is a bottom view showing the lead frame with the holding member and the like formed thereon.

FIG. 19 is a plan view showing the separated holding member and the like.

FIG. 20 is a front view showing a circuit board on which the element placement unit is mounted.

### DESCRIPTION OF EMBODIMENTS

Hereinafter, an embodiment of an element placement unit, a method for manufacturing an electrode portion, and a method for manufacturing a smoke detector according to the invention will be described in detail with reference to the drawings. Incidentally, the invention is not limited by the embodiment.

### Basic Concept of Embodiment

First, the basic concept of the embodiment will be described.

The “element placement unit” is a unit for placing a light emitting element and a light receiving element of a smoke detector that detects smoke by receiving scattered light caused by the scattering of light from the light emitting element by the smoke, using the light receiving element, and includes, for example, a light emitting element-side electrode portion and a light receiving element-side electrode portion.

The “light emitting element-side electrode portion” is a conductive element for placing the light emitting element while electrically connecting the light emitting element, and the “light receiving element-side electrode portion” is a conductive element for placing the light receiving element while electrically connecting the light receiving element. Further, the light emitting element-side electrode portion and the light receiving element-side electrode portion are integrally formed on a common frame body.

Further, in the embodiment shown below, each component of this application will be described by providing an example of a smoke detector installed on a ceiling that is an installation surface.

### Specific Contents of Embodiment

Next, specific contents of the embodiment will be described.

### (Configuration)

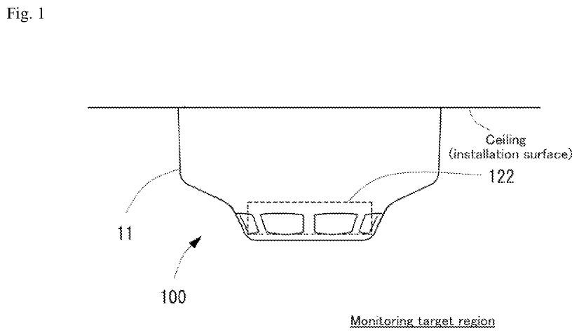

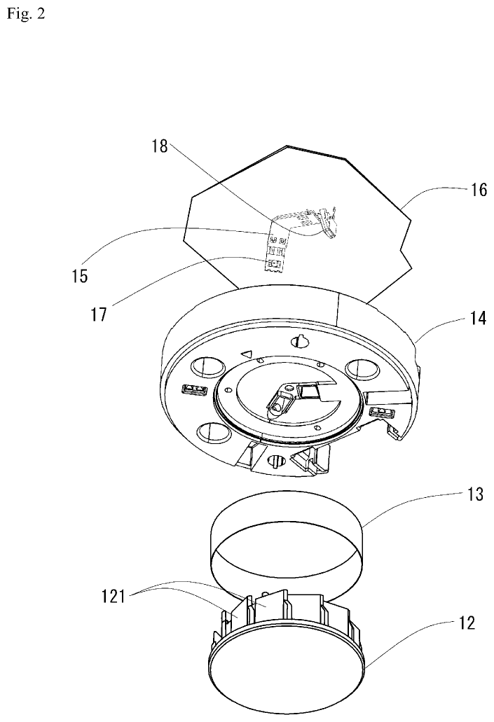

First, a configuration of the detector will be described. FIG. 1 is a view for describing an installation state of the detector, and FIG. 2 is an exploded perspective view of some components of the detector.

A detector 100 in FIG. 1 is a smoke detector that is installed on a ceiling which is an installation surface of a monitoring target region, and that detects a fire occurring in the monitoring target region. Incidentally, the “monitoring target region” is a region to be monitored by the detector 100, and is a concept including, for example, a room, staircase, any other regions, or the like of a building.

Incidentally, in the example of FIG. 1, a case where the detector 100 is directly installed on the installation surface is provided as an example; however, for example, the detector 100 may be configured to be installed via an attachment base.

The detector 100 includes, for example, an outer cover 11 in FIG. 1 and a smoke detection unit cover 12, an insect net 13, a smoke detection unit body 14, an element placement unit 15, a circuit board 16, a light emitting unit 17, and a light receiving unit 18 in FIG. 2. The circuit board 16 includes a light emission control circuit that drives the light emitting unit 17 to be described later, and a light reception processing circuit that processes a received light signal (photoelectrically converted signal) from the light receiving unit 18, and light emission-side connection portions 212 and light reception-side connection portions 312 to be described later are electrically connected to the light emission control circuit and the light reception processing circuit, respectively.

### (Configuration—Outer Cover, Smoke Detection Unit Cover, and Insect Net)

The outer cover 11 in FIG. 1 is a housing that houses components of the detector 100.

The smoke detection unit cover 12 in FIG. 2 forms a smoke detection space 122 (FIG. 1), and includes, for example, a labyrinth 121 that allows smoke to flow in or out of the smoke detection space 122 while shielding light from the outside.

The insect net 13 is a net that prevents insects from entering the smoke detection space 122, and has, for example, an annular shape to cover an outer periphery of the labyrinth 121.

### (Configuration—Smoke Detection Unit Body)

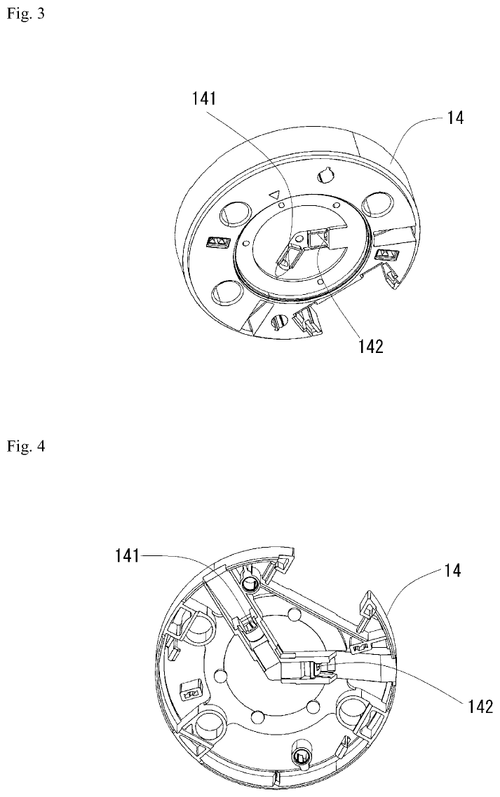

FIGS. 3 and 4 are perspective views of the smoke detection unit body. The smoke detection unit body 14 in FIG. 2 forms the smoke detection space 122 together with the smoke detection unit cover 12, and the circuit board 16 is attached to the smoke detection unit body 14. As shown in FIGS. 3 and 4, for example, the smoke detection unit body 14 includes an opening portion 141 for the light emitting element and an opening portion 142 for the light receiving element.

The opening portion 141 for the light emitting element is an opening portion for irradiating the smoke detection space 122 provided on a front side (side shown in FIG. 3) of the smoke detection unit body 14, with light from the light emitting unit 17 installed on a back side (side shown in FIG. 4) of the smoke detection unit body 14, and is, for example, an opening portion penetrating through the smoke detection unit body 14 from the back side to the front side.

The opening portion 142 for the light receiving element is an opening portion for irradiating the light receiving unit 18 installed on the back side of the smoke detection unit body 14, with light (specifically, scattered light) from the smoke detection space 122 provided on the front side of the smoke detection unit body 14, and is, for example, an opening portion penetrating through the smoke detection unit body 14 from the back side to the front side.

### (Configuration—Element Placement Unit)

The element placement unit 15 in FIG. 2 is an element placement unit on which the light emitting unit 17 and the light receiving unit 18 are placed, and is, for example, mounted on the circuit board 16. Incidentally, details of the element placement unit 15 will be described later.

(Configuration—circuit board)

The circuit board 16 in FIG. 2 is a board on which various electric circuits are mounted, and is, for example, a rigid board having a predetermined shape and provided on the back side of the smoke detection unit body 14.

(Configuration—light emitting unit)

The light emitting unit 17 in FIG. 2 is a light emitting element that irradiates the smoke detection space 122 with light, and is, for example, a light emitting diode (LED).

### (Configuration—Light Receiving Unit)

The light receiving unit 18 in FIG. 2 is a light receiving element irradiated with light (specifically, scattered light) from the smoke detection space 122 to detect the light, and is, for example, a photodiode (PD).

### (Configuration—Details—Element Placement Unit)

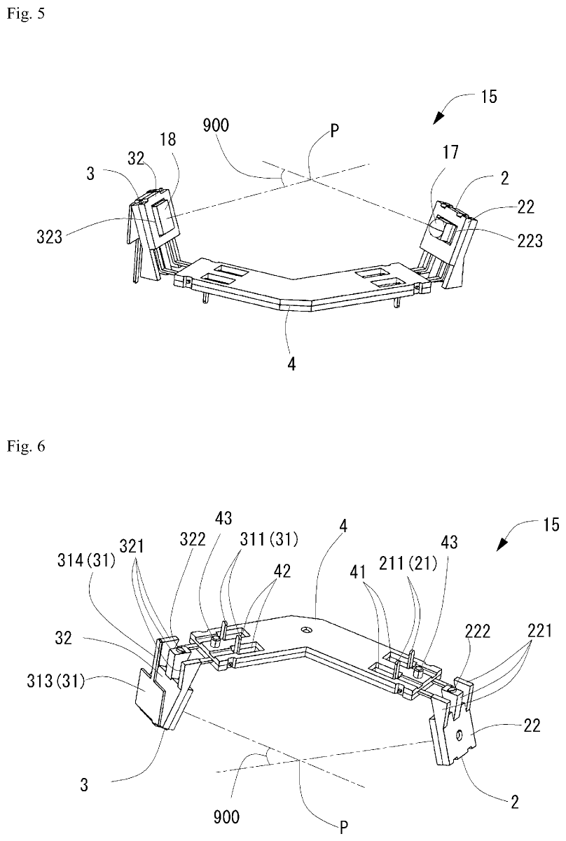

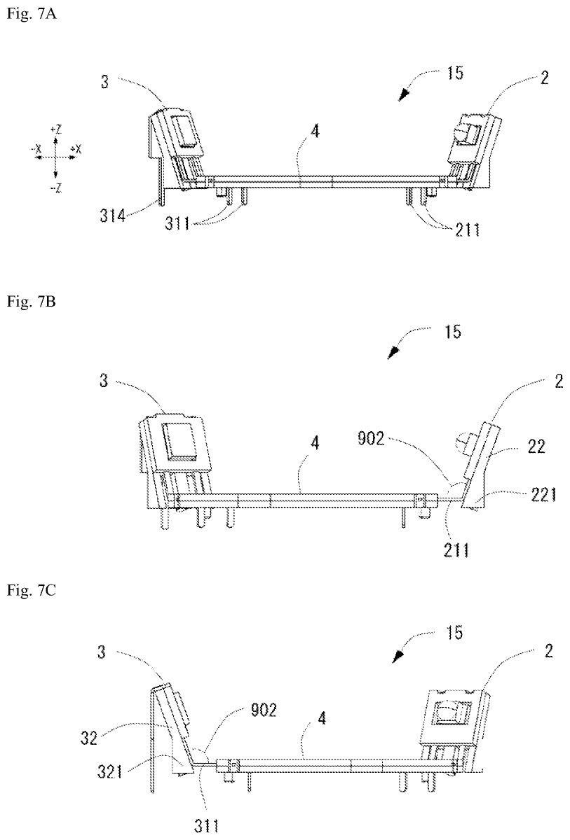

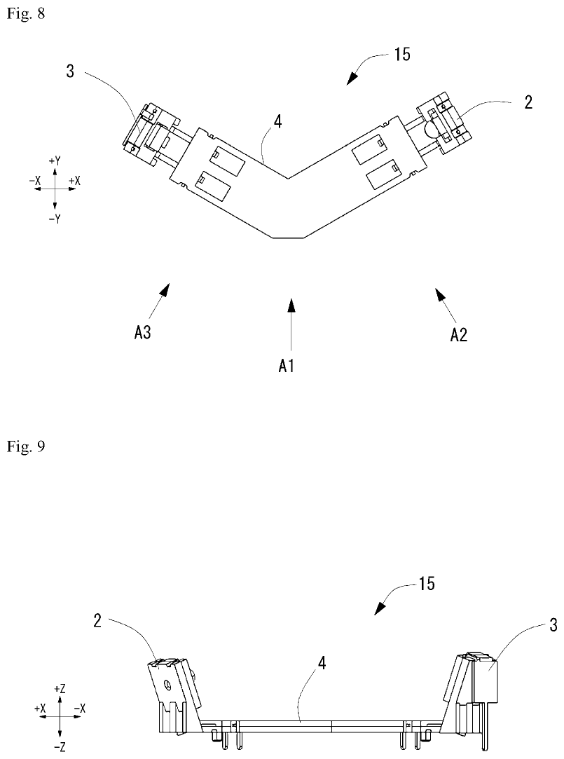

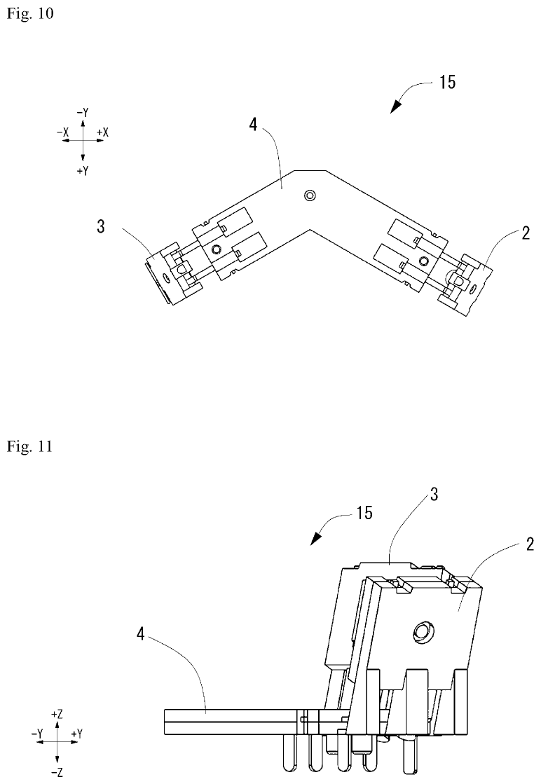

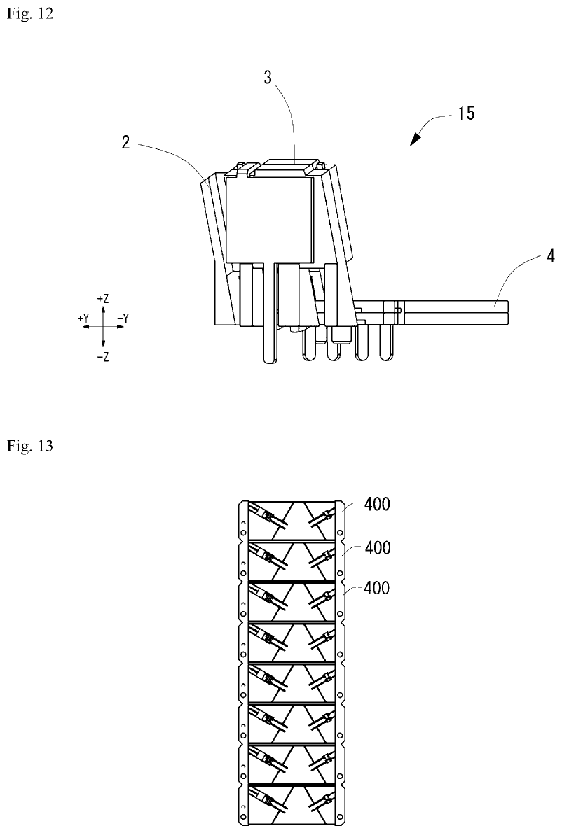

Next, details of the element placement unit 15 will be described. FIGS. 5 and 6 are perspective views of the element placement unit, FIGS. 7A to 7C are a front view of the element placement unit, FIG. 8 is a plan view of the element placement unit, FIG. 9 is a rear view of the element placement unit, FIG. 10 is a bottom view of the element placement unit, FIG. 11 is a right side view of the element placement unit, and FIG. 12 is a left side view of the element placement unit.

Incidentally, in FIGS. 5 and 6, optical axes of the light emitting unit 17 and the light receiving unit 18 are shown by alternating long and short dashed lines. In addition, it may be interpreted that the optical axis shown by an alternating long and short dashed line and extending from the light emitting unit 17 corresponds to a “light emitting axis” and the optical axis extending from the light receiving unit 18 corresponds to a “light receiving axis”. In addition, FIGS. 7A, 7B, and 7C show states when viewed in a direction A1, a direction A2, and a direction A3 in FIG. 8. In addition, in FIGS. 7A to 12, X-Y-Z axes are described as being orthogonal to each other.

The element placement unit 15 in FIG. 2 is an element placement unit on which the light emitting unit 17 and the light receiving unit 18 are placed, and is, for example, attached and fixed to the circuit board 16. As shown in FIGS. 5 and 6, for example, the element placement unit 15 holds the light emitting unit 17 and the light receiving unit 18 so as to form a scattering angle 900 within a predetermined angle range.

The “scattering angle” 900 is an angle formed at an intersection point P where the optical axis of the light emitting unit 17 and the optical axis of the light receiving unit 18 intersect each other, is an angle represented by an intersection angle at the intersection point P, and specifically, is an angle on a plane passing through each of the optical axes forming the intersection point P. Incidentally, in the detector 100, actually, the intersection point P is formed in the smoke detection space 122 (FIG. 1).

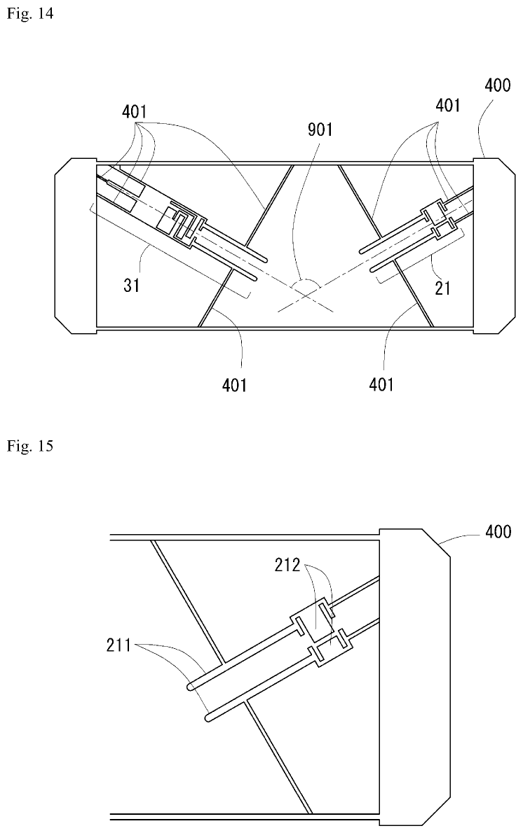

Further, the specific angle of the scattering angle 900 is any angle, but is preferably set to, for example, approximately 60 degrees to 90 degrees to reduce sensitivity differences for various smoke particle sizes, and in the present embodiment, is configured to be within this angle range. In addition, in the present embodiment, the angle of the scattering angle 900 is determined by a first element angle 901 (FIG. 14 to be described later) and second element angles 902 (FIGS. 7B and 7C).

Incidentally, as shown in FIG. 14 to be described later, the “first element angle” 901 is determined by directions in which a light emission-side electrode portion 21 and a light reception-side electrode portion 31 are directed in a lead frame 400.

In addition, as shown in FIGS. 7B and 7C, the “second element angles” 902 are determined by the inclination of a light emission-side holding portion 22 and a light reception-side holding portion 32 with respect to a holding member 4. Incidentally, the angles of the two second element angles 902 may be the same angle as each other or may be angles different from each other.

The element placement unit 15 in FIGS. 5 and 6 includes, for example, a light emission-side placement portion 2, a light reception-side placement portion 3, and the holding member 4.

### (Configuration—Details—Element Placement Unit—Light Emission—Side Placement Portion)

The light emission-side placement portion 2 in FIGS. 5 and 6 is a portion for mounting the light emitting unit 17 on the circuit board 16, and includes, for example, the light emission-side electrode portion 21 (also refer to FIG. 14 to be described later) and the light emission-side holding portion 22 (FIGS. 5 and 6).

### (Configuration—Details—Element Placement Unit—Light Emission-Side Placement Portion—Light Emission-Side Electrode Portion)

The light emission-side electrode portion 21 (also refer to FIG. 14 to be described later) is a light emitting element-side electrode portion having conductivity for placing the light emitting unit 17 on the circuit board 16 while electrically connecting the light emitting unit 17 to an electric circuit of the circuit board 16, and is, for example, a metal portion. The light emission-side electrode portion 21 includes, for example, light emission-side lead portions 211 (FIG. 6) and the light emission-side connection portions 212 (also refer to FIG. 15 to be described later).

The light emission-side lead portions 211 are conductive wires electrically connected to an anode terminal and a cathode terminal of the light emitting unit 17 mounted on the light emission-side placement portion 2, and parts of the light emission-side lead portions 211 are held by the holding member 4. As shown in FIG. 6, for example, parts on a tip side of the light emission-side lead portions 211 are folded inside an opening portion 41 for the light emission-side leads, and protrude toward the back side (−Z direction in FIG. 7A and the like). As shown in FIG. 7B parts on an opposite side of the light emission-side lead portions 211 from the tip side are folded by the second element angle 902.

The light emission-side connection portions 212 (also refer to FIG. 15 to be described later) are portions that are continuous from the light emission-side lead portions 211, and are portions with which the anode terminal and the cathode terminal of the light emitting unit 17 mounted on the light emission-side placement portion 2 come into contact, and which are electrically connected thereto.

### (Configuration—Details—Element Placement Unit—Light Emission—Side Placement Portion—Light Emission—Side Holding Portion)

The light emission-side holding portion 22 in FIGS. 5 and 6 is an insulating portion (for example, a resin portion) that holds a part of the light emission-side electrode portion 21, is a portion having a substantially rectangular shape as a whole, and includes a light emission-side support portion 221 (FIG. 6), a light emission-side protrusion portion 222 (FIG. 6), and a light emission-side opening portion 223 (FIG. 5).

The light emission-side support portion 221 is a support portion that supports the light emission-side holding portion 22, and is, for example, a portion configured to support the light emission-side holding portion 22 in a state where the light emission-side holding portion 22 is inclined by the second element angle 902 with respect to the holding member 4 (FIG. 7B) provided on the circuit board 16 and parallel to the circuit board 16.

The light emission-side protrusion portion 222 is a protrusion portion for positioning the light emission-side placement portion 2 with respect to the circuit board 16, and is, for example, a portion inserted into a hole or groove provided at a predetermined position on the circuit board 16.

The light emission-side opening portion 223 is a substantially rectangular opening portion provided at a position on the light emission-side holding portion 22 where the light emitting unit 17 is attached, and is, for example, an opening portion that exposes the light emission-side connection portions 212 (also refer to FIG. 15 to be described later).

### (Configuration—Details—Element Placement Unit—Light Reception—Side Placement Portion)

The light reception-side placement portion 3 in FIGS. 5 and 6 is a portion for mounting the light receiving unit 18 on the circuit board 16, and includes, for example, the light reception-side electrode portion 31 (also refer to FIG. 14 to be described later) and the light reception-side holding portion 32 (FIGS. 5 and 6).

### (Configuration—Details—Element Placement Unit—Light Reception—Side Placement Portion—Light Reception—Side Electrode Portion)

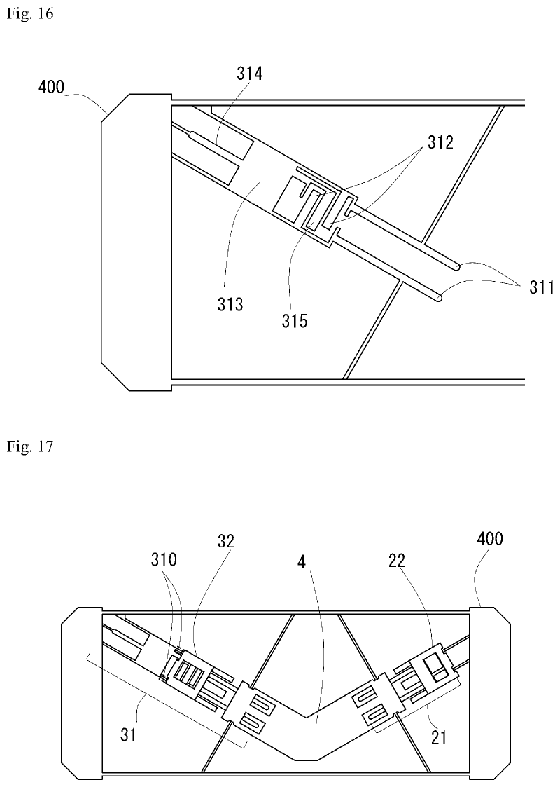

The light reception-side electrode portion 31 (also refer to FIG. 14 to be described later) is a light receiving element-side electrode portion having conductivity for placing the light receiving unit 18 on the circuit board 16 while electrically connecting the light receiving unit 18 to an electric circuit of the circuit board 16, and is, for example, a metal portion. The light reception-side electrode portion 31 includes, for example, light reception-side lead portions 311 (FIG. 6), the light reception-side connection portions 312 (also refer to FIG. 16 to be described later), a shield portion 313 (FIG. 6), a shield-side lead portion 314 (FIG. 6), and a shield-side connection portion 315 (also refer to FIG. 16 to be described later).

The light reception-side lead portions 311 are conductive wires electrically connected to an anode terminal and a cathode terminal of the light receiving unit 18 mounted on the light reception-side placement portion 3, and parts of the light reception-side lead portions 311 are held by the holding member 4. As shown in FIG. 6, for example, parts on a tip side of the light reception-side lead portions 311 are folded inside an opening portion 42 for the light reception-side leads, and protrude toward the back side (−Z direction in FIG. 7A and the like). As shown in FIG. 7C, parts on an opposite side of the light reception-side lead portions 311 from the tip side are folded by the second element angle 902.

The light reception-side connection portions 312 (also refer to FIG. 16 to be described later) are portions that are continuous from the light reception-side lead portions 311, and are portions with which the anode terminal and the cathode terminal of the light receiving unit 18 mounted on the light reception-side placement portion 3 come into contact, and which are electrically connected thereto.

The shield portion 313 is a shield portion functioning as a shield for the prevention of noise or the reduction of noise of the light receiving unit 18 mounted on the light reception-side placement portion 3, and is a portion provided on a back side of the light receiving unit 18. In addition, the shield portion 313 is a portion formed by extending from a part of the light reception-side electrode portion 31.

The shield-side lead portion 314 is a conductive wire electrically connected to the shield portion 313, and is, for example, a portion of which a tip side protrudes toward the back side (−Z direction in FIG. 7A and the like).

The shield-side connection portion 315 (also refer to FIG. 16 to be described later) is a portion that is continuous from the shield portion 313, and is a portion that comes into contact with a case of the light receiving unit 18 mounted on the light reception-side placement portion 3.

### (Configuration—Details—Element Placement Unit—Light Reception—Side Placement Portion—Light Reception—Side Holding Portion)

The light reception-side holding portion 32 in FIGS. 5 and 6 is an insulating portion (for example, a resin portion) that holds a part of the light reception-side electrode portion 31, is a portion having a substantially rectangular shape as a whole, and includes a light reception-side support portion 321 (FIG. 6), a light reception-side protrusion portion 322 (FIG. 6), and a light reception-side opening portion 323 (FIG. 5).

The light reception-side support portion 321 is a support portion that supports the light reception-side holding portion 32, and is, for example, a portion configured to support the light reception-side holding portion 32 in a state where the light reception-side holding portion 32 is inclined by the second element angle 902 with respect to the holding member 4 (FIG. 7C) provided on the circuit board 16 and parallel to the circuit board 16.

The light reception-side protrusion portion 322 is a protrusion portion for positioning the light reception-side placement portion 3 with respect to the circuit board 16, and is, for example, a portion inserted into a hole or groove provided at a predetermined position on the circuit board 16.

The light reception-side opening portion 323 is a substantially rectangular opening portion provided at a position on the light reception-side holding portion 32 where the light receiving unit 18 is attached, and is, for example, an opening portion that exposes the light reception-side connection portions 312 and the shield-side connection portion 315 (also refer to FIG. 16 to be described later).

### (Configuration—Details—Element Placement Unit—Holding Member)

The holding member 4 in FIG. 6 is an insulating member (for example, a resin member) that holds the light emission-side electrode portion 21 and the light reception-side electrode portion 31, and as shown in FIG. 8, for example, is an insulating member bent to form a predetermined angle (specifically, the first element angle 901 (FIG. 14 to be described later)) in a plan view.

As shown in FIG. 6, for example, the holding member 4 includes the opening portion 41 for the light emission-side leads, the opening portion 42 for the light reception-side leads, and a holding member-side protrusion portion 43.

The opening portion 41 for the light emission-side leads is a penetrating opening portion provided at a position toward the light emission-side holding portion 22, and is an opening portion inside which the parts on the tip side of the light emission-side lead portions 211 are disposed.

The opening portion 42 for the light reception-side leads is a penetrating opening portion provided at a position toward the light reception-side holding portion 32, and is an opening portion inside which the parts on the tip side of the light reception-side lead portions 311 are disposed.

The holding member-side protrusion portion 43 is a protrusion portion for positioning the holding member 4 with respect to the circuit board 16, and is, for example, a portion inserted into a hole or groove provided at a predetermined position on the circuit board 16.

### (Method for Manufacturing Element Placement Unit)

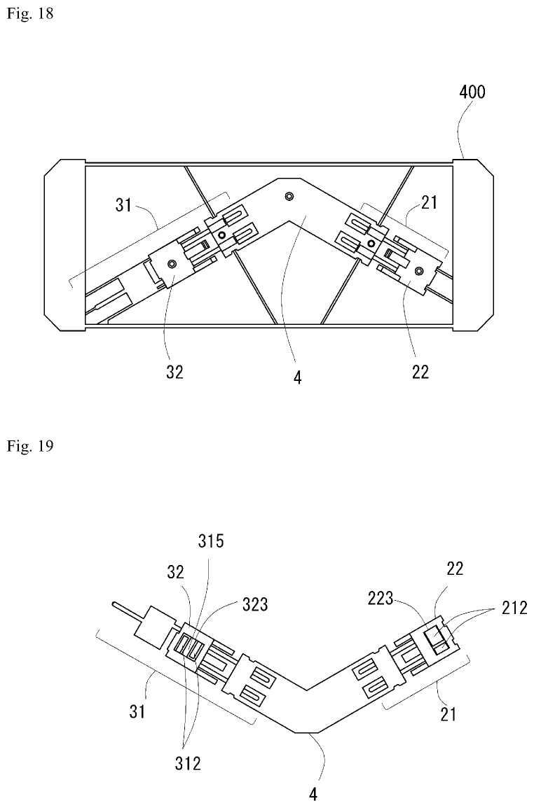

Next, a method for manufacturing the element placement unit 15 configured in such a manner will be described. FIG. 13 is a plan view of a plurality of lead frames, FIG. 14 is a plan view of one lead frame, FIGS. 15 and 16 are partial enlarged views of FIG. 14, FIG. 17 is a plan view showing a lead frame with the holding member and the like are formed thereon, FIG. 18 is a bottom view showing the lead frame with the holding member and the like are formed thereon, and FIG. 19 is a plan view showing the separated holding member and the like.

Incidentally, the “lead frame” 400 is a lead frame body, schematically, is a metal object, and includes, for example, elements forming at least a part of the element placement unit 15.

### ===Formation of Light Emission-Side Electrode Portion and Light Reception-Side Electrode Portion===

First, as shown in FIG. 14, the light emission-side electrode portion 21 and the light reception-side electrode portion 31 are formed. Incidentally, during actual manufacturing, a plurality of the lead frames 400 each including the light emission-side electrode portion 21 and the light reception-side electrode portion 31 are collectively formed; however, in the present embodiment, one lead frame 400 will be focused and described. Here, for example, as shown in FIGS. 14 to 16, the light emission-side electrode portion 21 and the light reception-side electrode portion 31 made of metal with a predetermined thickness (for example, approximately 1 mm to 3 mm or the like) are integrally formed on one lead frame 400 using any method (for example, a method for pressing metal using a mold or other known methods).

Particularly, as shown in FIG. 14, the light emission-side electrode portion 21 and the light reception-side electrode portion 31 are formed such that the first element angle 901 that is an angle determined by the directions in which the electrode portions extend (directions shown by alternating long and short dashed lines in FIG. 14) can form the scattering angle 900 of an appropriate angle (FIGS. 5 and 6) (namely, as described above, for example, the scattering angle 900 of approximately 60 degrees to 90 degrees), but as one example, may be formed such that the first element angle 901 becomes 120 degrees.

Incidentally, here, for example, in order to fix the light emission-side electrode portion 21 and the light reception-side electrode portion 31 to the lead frame 400, a plurality of fixing portions 401 are also integrally formed.

In addition, here, for example, the light emission-side electrode portion 21 and the light reception-side electrode portion 31 may be simultaneously formed, or after the light emission-side electrode portion 21 is formed, the light reception-side electrode portion 31 may be formed, or conversely, after the light reception-side electrode portion 31 is formed, the light emission-side electrode portion 21 may be formed.

### ===Holding of Light Emission-Side Electrode Portion and Light Reception-Side Electrode Portion==

Next, as shown in FIGS. 17 and 18, the light emission-side electrode portion 21 and the light reception-side electrode portion 31 (FIG. 14) are held by the common holding member 4. Here, for example, as shown in FIGS. 17 and 18, the holding member 4, the light emission-side holding portion 22, and the light reception-side holding portion 32 are integrally formed on one lead frame 400 using any method (for example, a method using insert molding or other known methods).

Incidentally, here, for example, the holding member 4, the light emission-side holding portion 22, and the light reception-side holding portion 32 may be simultaneously formed, or may be sequentially formed in any order.

### ===Separation of Holding Member and the Like===

Next, as shown in FIG. 19, the light emission-side electrode portion 21, the light reception-side electrode portion 31, the holding member 4, the light emission-side holding portion 22, and the light reception-side holding portion 32 (hereinafter, also referred to as “each element of the element placement unit 15”) are separated from other portions of the lead frame 400. Here, for example, each element of the element placement unit 15 is separated by cutting connection portions with the plurality of fixing portions 401 shown in FIG. 14.

Incidentally, here, for example, two removal portions 310 shown in FIG. 17 as a part of the light reception-side electrode portion 31 are also removed. For example, since each of two light reception-side lead portions 311 in FIG. 16 is separated from the shield portion 313 by this procedure, the two light reception-side lead portions 311 are electrically separated from each other.

===Folding of lead portion (namely, bending of lead portion)===Next, as shown in FIGS. 5 to 12, the element placement unit 15 is formed by folding the light emission-side electrode portion 21 and the light reception-side electrode portion 31 at predetermined positions. Accordingly, the element placement unit 15 is manufactured.

### (Method for Manufacturing Detector)

Next, a method for manufacturing the detector 1 will be described.

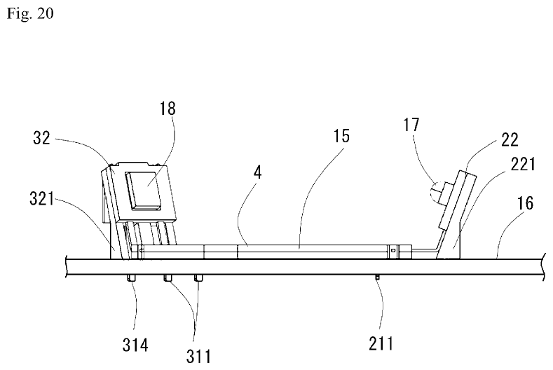

FIG. 20 is a front view showing the circuit board on which the element placement unit is mounted. Incidentally, a hole or groove into which each protrusion portion of the element placement unit 15 is inserted for positioning is provided in a surface (upper surface of the drawing of FIG. 20) of the circuit board 16, and the circuit board 16 is provided with insertion holes into which the light emission-side lead portions 211, the light reception-side lead portions 311, and the shield-side lead portion 314 provided in the positioned element placement unit 15 are inserted.

### ===Mounting of Each Element===

First, the light emitting unit 17 and the light receiving unit 18 are mounted on the element placement unit 15 manufactured as described above. Here, for example, as shown in FIG. 5, the light emitting unit 17 is provided in the light emission-side opening portion 223 (also refer to FIG. 19), and the light receiving unit 18 is provided in the light reception-side opening portion 323 (also refer to FIG. 19). The specific fixing method is any method, but for example, fixing may be performed by engagement or fixing may be performed using an adhesive agent (incidentally, unless otherwise specified, the same applies to a method for fixing other elements).

In this case, for example, the anode terminal and the cathode terminal of the light emitting unit 17 are electrically connected to the light emission-side connection portions 212 in FIG. 19, namely, are electrically connected to the light emission-side lead portions 211 (FIG. 6).

In addition, in this case, for example, the anode terminal and the cathode terminal of the light receiving unit 18 are electrically connected to the light reception-side connection portions 312 in FIG. 19, namely, are electrically connected to the light reception-side lead portions 311 (FIG. 6).

### ===Mounting of Element Placement Unit===

Next, as shown in FIG. 20, the element placement unit 15 is mounted by being fixed to the circuit board 16. Here, for example, the element placement unit 15 is positioned by inserting each protrusion portion of the element placement unit 15 into the positioning hole or groove of the circuit board 16, and tip sides of the light emission-side lead portions 211, the light reception-side lead portions 311, and the shield-side lead portion 314 are inserted and fixed to the insertion holes of the circuit board 16.

Incidentally, in this case, since the holding member 4 is parallel to the circuit board 16 and the light emission-side holding portion 22 and the light reception-side holding portion 32 are supported by the light emission-side support portion 221 and the light reception-side support portion 321, as shown in FIGS. 7B and 7C, a state where the second element angle 902 is a predetermined angle (angle determined in advance at which the angle of the scattering angle 900 (FIGS. 5 and 6) is, for example, approximately 60 degrees to 90 degrees) is maintained.

Thereafter, the mounting of the element placement unit 15 is completed by connecting the light emission-side lead portions 211, the light reception-side lead portions 311, and the shield-side lead portion 314 protruding from a back surface (lower surface of the drawing of FIG. 20) of the circuit board 16 in FIG. 20, to the electric circuits (including wiring patterns) of the circuit board 16, a ground pattern, or the like using solder or the like.

### ===Attachment of Each Element===

Next, as shown in FIG. 2, the circuit board 16 with the element placement unit 15 mounted thereon is fixed to the back side of the smoke detection unit body 14 using any method (for example, a fixing method using fixing screws or the like). Incidentally, in this case, the optical axes of the light emitting unit 17 and the light receiving unit 18 shown in FIGS. 5 and 6 pass through the opening portion 141 for the light emitting element and the opening portion 142 for the light receiving element in FIGS. 3 and 4, and reach the front side of the smoke detection unit body 14.

Next, the smoke detection unit cover 12 with the insect net 13 attached thereto is fixed to the front side of the smoke detection unit body 14 using any method (for example, a fixing method by engaging attachment projections, a method using an adhesive agent, or the like).

Next, the outer cover 11 (FIG. 1) is fixed to the smoke detection unit body 14 and the like using any method (for example, a fixing method using fixing screws or the like). Further, in this case, the smoke detection space 122 shown in FIG. 1 is formed, and the intersection point P in FIGS. 5 and 6 are provided in the smoke detection space 122. Accordingly, the detector 1 is manufactured.

### (Operation of Detector)

Next, the operation of the detector 1 will be described. Since the operation of the detector 1 is known, only a brief description will be given. Here, for example, as shown in FIG. 1, a case where the detector 100 is installed on a ceiling will be described.

When a fire has occurred in the monitoring target region, smoke particles flow into the smoke detection space 122 via opening portions of the outer cover 11 of the detector 100. In this case, light output from the light emitting unit 17 in FIGS. 5 and 6 is scattered by the smoke particles that have flowed in, and scattered light that is light caused by the scattering is detected by the light receiving unit 18, so that the detector 100 detects the fire.

### Effects of Embodiment

As described above, according to the present embodiment, by providing the light emission-side electrode portion 21 and the light reception-side electrode portion 31, for example, the light emitting unit 17 and the light receiving unit 18 can be easily attached to the detector 100. In addition, by integrally forming the light emission-side electrode portion 21 and the light reception-side electrode portion 31 on the common lead frame 400, for example, the element placement unit 15 can be easily formed.

In addition, by disposing the light emission-side electrode portion 21 and the light reception-side electrode portion 31 so as to correspond to the first element angle 901 forming the scattering angle 900, for example, the scattering angle 900 of an appropriate angle (for example, approximately 60 degrees to 90 degrees) can be reliably and easily formed in the detector 100.

In addition, by integrally forming the shield portion 313 on the lead frame 400, for example, a shield for the light receiving unit 18 can be provided in the element placement unit 15.

In addition, by forming the shield portion 313 through extending from a part of the light reception-side electrode portion 31, for example, the shield portion 313 can be formed integrally with the light reception-side electrode portion 31, and the shield portion 313 can be easily formed.

In addition, by providing the holding member 4 that holds the light emission-side electrode portion 21 and the light reception-side electrode portion 31, for example, the light emission-side electrode portion 21, the light reception-side electrode portion 31, and the holding member 4 can be integrated into one unit, and handling can be facilitated.

In addition, by electrically connecting the light emitting unit 17 and the light receiving unit 18 to the electric circuits of the circuit board 16 of the detector 100 via the light emission-side lead portions 211 and the light reception-side lead portions 311, for example, the light emitting unit 17 and the light receiving unit 18 can be reliably and easily electrically connected to the electric circuits.

In addition, by electrically connecting the shield portion 313 to an electric circuit ground (predetermined circuit ground) of the circuit board 16 of the detector 100, for example, the electromagnetic shielding effect of the shield portion 313 (the effect of preventing an influence of electrical or magnetic disturbance noise on the element or the effect of reducing the influence) can be improved.

In addition, by forming the light emission-side electrode portion 21 and by forming the light reception-side electrode portion 31, for example, the light emitting unit 17 and the light receiving unit 18 can be easily attached to the detector 100. In addition, by integrally forming the light emission-side electrode portion 21 and the light reception-side electrode portion 31 on the common lead frame 400, for example, the element placement unit 15 can be easily formed.

In addition, by holding the light emission-side electrode portion 21 and the light reception-side electrode portion 31 using the common holding member 4, and by separating the light emission-side electrode portion 21, the light reception-side electrode portion 31, and the holding member 4 from the common lead frame 400, for example, the light emission-side electrode portion 21, the light reception-side electrode portion 31, and the holding member 4 can be integrated into one unit, and can be easily separated from the common lead frame 400.

In addition, by bending the light emission-side electrode portion 21 and the light reception-side electrode portion 31 according to the scattering angle, for example, the scattering angle 900 of an appropriate angle (for example, approximately 60 degrees to 90 degrees) can be reliably and easily formed in the detector 100.

In addition, the element placement unit 15, in which the light emitting unit 17 and the light receiving unit 18 are placed to be electrically connected to the light emission-side electrode portion 21 and the light reception-side electrode portion 31 integrally held by the holding member 4 respectively, is electrically connected to the electric circuits of the circuit board of the detector 100, so that for example, the light emitting unit 17 and the light receiving unit 18 can be easily attached to the detector 100. In addition, by electrically connecting the light emitting unit 17 and the light receiving unit 18 via the light emission-side lead portions 211 and the light reception-side lead portions 311, for example, the light emitting unit 17 and the light receiving unit 18 can be reliably and easily electrically connected to the electric circuits.

### Modification Examples of Embodiment

The embodiment according to the invention has been described above, but the specific configurations, units, and portions of the invention can be modified and improved in any manner within the scope of the technical concept of each invention described in the appended claims. Hereinafter, such modification examples will be described.

### (Regarding Problems to be Solved and Effects of Invention)

First, the problems to be solved by the invention and the effects of the invention are not limited to the above-described contents, and may differ depending on details of implementation environments or configurations of the invention, and only some of the above-described problems may be solved, or only some of the above-described effects may be obtained.

### (Regarding Dispersion and Integration)

In addition, the above-described configurations are conceptual representations of functions, and do not necessarily need to be physically configured as shown in the drawings. Namely, the specific forms of the dispersion or integration of each portion are not limited to those shown in the drawings, and all or some thereof can be configured to be functionally or physically dispersed or integrated in any unit.

### (Regarding Shield Portion)

In addition, the shield portion 313 in FIG. 16 of the embodiment may be changed in any manner. For example, the shield portion 313 may be configured separately from other portions of the light reception-side electrode portion 31. In this case, for example, after the light reception-side lead portions 311 and the light reception-side connection portions 312 are formed, the shield portion may be formed at a position away from these elements.

In addition, for example, the shield-side lead portion 314 may be omitted, and the shield portion 313 may be connected not to be electrically connected to the circuit board 16. In addition, for example, the shield-side connection portion 315 may be omitted. In addition, for example, a shield portion functioning as an electromagnetic shield portion for the light emitting unit 17 may be provided.

In addition, in the embodiment, as shown in FIG. 20, the case has been described in which the light emission-side lead portions 211, the light reception-side lead portions 311, and the shield-side lead portion 314 are electrically connected to the electric circuits (including wiring patterns), the ground pattern, or the like on the back side (lower side of the drawing of FIG. 20) of the circuit board 16 in a state where the light emission-side lead portions 211, the light reception-side lead portions 311, and the shield-side lead portion 314 are inserted into the insertion holes of the circuit board 16; however, the invention is not limited to the case. For example, after the electric circuits (including wiring patterns), the ground pattern, or the like are formed on the front side (upper side of the drawing of FIG. 20) of the circuit board 16, the light emission-side lead portions 211, the light reception-side lead portions 311, and the shield-side lead portion 314 may be configured to be electrically connected to the electric circuits or the like. Specifically, for example, after the light emission-side lead portions 211 and the light reception-side lead portions 311 are aligned along the back surface (surface in the −Z direction) of the holding member 4 by folding the tip sides of the light emission-side lead portions 211, the light reception-side lead portions 311, and the shield-side lead portion 314 shown in FIG. 7A so as to be parallel to the holding member 4, the light emission-side lead portions 211 and the light reception-side lead portions 311 may be configured to be electrically connected to the electric circuits or the like provided on the front side of the circuit board 16 described above using solder or the like. In the case of implementing the configuration in such a manner, since the element placement unit 15 can be surface-mounted on the circuit board 16, the insertion hole for inserting each lead portion described above is not required.

Incidentally, here, the direction in which each lead portion is folded is any direction, but for example, the tip side of the light emission-side lead portions 211 in FIG. 6 may be folded toward the light emission-side holding portion 22 side (namely, the right side of the drawing of FIG. 6), and the tip side of the light reception-side lead portions 311 in FIG. 6 may be folded toward the light reception-side holding portion 32 side (namely, the left side of the drawing of FIG. 6). In the case of performing folding in such a manner, at ends of the opening portion 41 for the light emission-side leads and the opening portion 42 for the light reception-side leads, each lead portion can be brought into contact with a part of the holding member 4 and can be folded with the contacted part of the holding member 4 as a starting point, so that workability can be improved.

### (Regarding Number of Light Emission-Side Electrode Portions and Light Reception-Side Electrode Portions)

In addition, in the embodiment, the case has been described in which one light emission-side electrode portion 21 and one light reception-side electrode portion 31 are provided for one element placement unit 15; however, the invention is not limited to the case. For example, a plurality of only one or both of the light emission-side electrode portions 21 and the light reception-side electrode portions 31 may be provided.

For example, when two light emission-side electrode portions 21 are provided and one light reception-side electrode portion 31 is provided, two light emitting units 17 and one light receiving unit 18 can be provided for one detector 100. In this case, a combination of a wavelength difference and a scattering angle distribution can be used, and for example, the configuration may be such that one light emitting unit 17 emitting near-infrared or red light is disposed on a forward scattering side (namely, such that the light receiving unit 18 receives forward scattered light thereof), another light emitting unit 17 emitting blue light is disposed on a rearward scattering side, and both scattered lights received by the light receiving unit 18 are compared to each other.

In addition, for example, when one light emission-side electrode portion 21 is provided and two light reception-side electrode portions 31 are provided, one light emitting unit 17 and two light receiving units 18 can be provided for one detector 100. In this case, a scattering angle distribution can be used, and for example, the configuration may be such that forward scattered light of the light emitting unit 17 emitting near-infrared light is received by one light receiving unit 18, rearward scattered light of the light emitting unit 17 is received by another light receiving unit 18, and the received forward scattered light and rearward scattered light are compared to each other.

Further, in the case of implementing the configuration as described above, for example, since a plurality of the light emitting units 17 or the light receiving units 18 can be provided for one detector 100, the performance of the detector 10 can be improved. Namely, for example, it is possible to distinguish between white smoke and black smoke in smoke of a fire (namely, distinguish between types of fires (combustion source)) or to distinguish between smoke of a fire and others (for example, dust, steam, oil smoke from cooking, and the like).

Incidentally, by providing three or more of only one or both of the light emission-side electrode portions 21 and the light reception-side electrode portions 31, three or more of only one or both of the light emitting units 17 and the light receiving units 18 may be provided for one detector 100.

### (Regarding Features)

In addition, the configurations of the embodiment and the features of the modification examples may be combined in any manner.

One embodiment of the present invention provides an element placement unit for placing a light emitting element and a light receiving element of a smoke detector that detects smoke by receiving scattered light caused by a scattering of light from the light emitting element by the smoke, using the light receiving element, the unit comprises: a light emitting element-side electrode portion having conductivity for placing the light emitting element while electrically connecting the light emitting element; and a light receiving element-side electrode portion having conductivity for placing the light receiving element while electrically connecting the light receiving element, wherein the light emitting element-side electrode portion and the light receiving element-side electrode portion are integrally formed on a common frame body.

According to this embodiment, by providing the light emission-side electrode portion and the light reception-side electrode portion, for example, a light emitting element and a light receiving element can be easily attached to a smoke detector. In addition, by integrally forming the light emission-side electrode portion and the light reception-side electrode portion on a common frame body, for example, the element placement unit can be easily formed.

Another embodiment of the present invention provides the element placement unit according to the above embodiment, wherein the light emitting element-side electrode portion and the light receiving element-side electrode portion are disposed to correspond to a first element angle forming a scattering angle represented by an intersection angle between a light emitting axis of the light emitting element and a light receiving axis of the light receiving element.

According to this embodiment, by disposing the light emission-side electrode portion and the light reception-side electrode portion so as to correspond to a first element angle forming a scattering angle for example, the scattering angle of an appropriate angle (for example, approximately 60 degrees to 90 degrees) can be reliably and easily formed in the smoke detector.

Another embodiment of the present invention provides the element placement unit according to the above embodiment, wherein a shield portion functioning as an electromagnetic shield for the light receiving element is formed integrally with the light emitting element-side electrode portion and the light receiving element-side electrode portion on the common frame body.

According to this embodiment, by integrally forming the shield portion on the frame body, for example, a shield for the light receiving element can be provided in the element placement unit.

Another embodiment of the present invention provides the element placement unit according to the above embodiment, wherein the shield portion is formed by extending from a part of the light receiving element-side electrode portion.

According to this embodiment, by forming the shield portion through extending from a part of the light reception-side electrode portion, for example, the shield portion can be formed integrally with the light reception-side electrode portion, and the shield portion can be easily formed.

Another embodiment of the present invention provides the element placement unit according to the above embodiment, further comprises an insulating member that holds the light emitting element-side electrode portion and the light receiving element-side electrode portion.

According to this embodiment, by providing an insulating member that holds the light emission-side electrode portion and the light reception-side electrode portion, for example, the light emission-side electrode portion, the light reception-side electrode portion, and the insulating member can be integrated into one unit, and handling can be facilitated.

Another embodiment of the present invention provides the element placement unit according to the above embodiment, wherein the element placement unit includes a plurality of sets of at least one of the light emitting element-side electrode portions and the light receiving element-side electrode portions.

According to this embodiment, by including a plurality of sets of at least one of the light emitting element-side electrode portions and the light receiving element-side electrode portions, for example, it is possible to provide a plurality of the light emitting element and a plurality of the light receiving element for one smoke detector, the performance of the smoke detector can be improved. Namely, for example, it is possible to distinguish between white smoke and black smoke in smoke of a fire (namely, distinguish between types of fires (combustion source)) or to distinguish between smoke of a fire and others (for example, dust, steam, oil smoke from cooking, and the like).

Another embodiment of the present invention provides the element placement unit according to the above embodiment, wherein the light emitting element-side electrode portion and the light receiving element-side electrode portion include lead portions, and the light emitting element and the light receiving element of the element placement unit are electrically connected to electric circuits of a circuit board of the smoke detector via the lead portions.

According to this embodiment, by electrically connecting the light emitting element and the light receiving element to electric circuits of a circuit board of the smoke detector via the lead portions of the light emitting element-side electrode portion and the light receiving element-side electrode portion, for example, the light emitting element and the light receiving element can be reliably and easily electrically connected to the electric circuits.

Another embodiment of the present invention provides the element placement unit according to the above embodiment, wherein a shield portion functioning as an electromagnetic shield for the light receiving element is formed integrally with the light emitting element-side electrode portion and the light receiving element-side electrode portion on the common frame body, and the shield portion is electrically connected to an electric circuit ground of a circuit board of the smoke detector.

According to this embodiment, by electrically connecting the shield portion to an electric circuit ground (predetermined circuit ground) of the circuit board of the smoke detector, for example, the electromagnetic shielding effect of the shield portion (the effect of preventing an influence of electrical or magnetic disturbance noise on the element or the effect of reducing the influence) can be improved.

Another embodiment of the present invention provides a method for manufacturing an electrode portion in an element placement unit for placing a light emitting element and a light receiving element of a smoke detector that detects smoke by receiving scattered light caused by a scattering of light from the light emitting element by the smoke, using the light receiving element, the method comprises: a step of integrally forming a light emitting element-side electrode portion having conductivity on a common frame body, the light emitting element-side electrode portion for placing the light emitting element while electrically connecting the light emitting element; and a step of integrally forming a light receiving element-side electrode portion having conductivity on the common frame body, the light receiving element-side electrode portion for placing the light receiving element while electrically connecting the light receiving element.

According to this embodiment, by forming the light emission-side electrode portion and by forming the light reception-side electrode portion, for example, the light emitting element and the light receiving element can be easily attached to the smoke detector In addition, by integrally forming the light emission-side electrode portion and the light reception-side electrode portion on the common frame body, for example, the element placement unit can be easily formed.

Another embodiment of the present invention provides a method for manufacturing an electrode portion in an element placement unit for placing a light emitting element and a light receiving element of a smoke detector that detects smoke by receiving scattered light caused by a scattering of light from the light emitting element by the smoke, using the light receiving element, the method comprises: a step of integrally forming a light emitting element-side electrode portion having conductivity on a common frame body, the light emitting element-side electrode portion for placing the light emitting element while electrically connecting the light emitting element; and a step of integrally forming a light receiving element-side electrode portion having conductivity on the common frame body, the light receiving element-side electrode portion for placing the light receiving element while electrically connecting the light receiving element, wherein the light emitting element-side electrode portion and the light receiving element-side electrode portion are disposed to correspond to a first element angle forming a scattering angle represented by an intersection angle between a light emitting axis of the light emitting element and a light receiving axis of the light receiving element.

According to this embodiment, by forming the light emission-side electrode portion and by forming the light reception-side electrode portion, for example, the light emitting element and the light receiving element can be easily attached to the smoke detector In addition, by integrally forming the light emission-side electrode portion and the light reception-side electrode portion on the common frame body, for example, the element placement unit can be easily formed. Further, by disposing the light emission-side electrode portion and the light reception-side electrode portion so as to correspond to a first element angle forming a scattering angle for example, the scattering angle of an appropriate angle (for example, approximately 60 degrees to 90 degrees) can be reliably and easily formed in the smoke detector.

Another embodiment of the present invention provides a method for manufacturing an electrode portion in an element placement unit for placing a light emitting element and a light receiving element of a smoke detector that detects smoke by receiving scattered light caused by a scattering of light from the light emitting element by the smoke, using the light receiving element, the element placement unit including a light emitting element-side electrode portion having conductivity for placing the light emitting element while electrically connecting the light emitting element and a light receiving element-side electrode portion having conductivity for placing the light receiving element while electrically connecting the light receiving element, and the light emitting element-side electrode portion and the light receiving element-side electrode portion being integrally formed on a common frame body, the method comprises: a step of forming a shield portion integrally with the light emitting element-side electrode portion and the light receiving element-side electrode portion on the common frame body, the shield portion functioning as an electromagnetic shield for the light receiving element.

According to this embodiment, by forming a shield portion functioning as an electromagnetic shield for the light receiving element, for example, a shield for the light receiving element can be provided.

Another embodiment of the present invention provides the method for manufacturing an electrode portion according to the above embodiment, further comprises: a step of holding the light emitting element-side electrode portion and the light receiving element-side electrode portion in the common frame body using a common insulating member; and a step of separating the light emitting element-side electrode portion, the light receiving element-side electrode portion, and the common insulating member from the common frame body.

According to this embodiment, by holding the light emission-side electrode portion and the light reception-side electrode portion using the common insulating member, and by separating the light emission-side electrode portion, the light reception-side electrode portion, and the common insulating member from the common frame body, for example, the light emission-side electrode portion, the light reception-side electrode portion, and the insulating member can be integrated into one unit, and can be easily separated from the common frame body.

Another embodiment of the present invention provides the method for manufacturing an electrode portion according to the above embodiment, further comprises: a step of bending the light emitting element-side electrode portion or the light receiving element-side electrode portion according to a scattering angle represented by an intersection angle between a light emitting axis of the light emitting element and a light receiving axis of the light receiving element.

According to this embodiment, by bending the light emission-side electrode portion and the light reception-side electrode portion according to the scattering angle, for example, the scattering angle of an appropriate angle (for example, approximately 60 degrees to 90 degrees) can be reliably and easily formed in the smoke detector.

Another embodiment of the present invention provides a method for manufacturing a smoke detector that detects smoke by receiving scattered light caused by a scattering of light from a light emitting element by the smoke, using a light receiving element, the method comprises: a step of electrically connecting an element placement unit, in which a light emitting element and a light receiving element are disposed to correspond to a first element angle forming a scattering angle represented by an intersection angle between a light emitting axis of the light emitting element and a light receiving axis of the light receiving element and in which the light emitting element and the light receiving element are placed to be electrically connected to the light emission-side electrode portion and the light reception-side electrode portion integrally held by an insulating member respectively, to an electric circuit of a circuit board of the smoke detector via a lead portion of each of the light emitting element-side electrode portion and the light receiving element-side electrode portion.

According to this embodiment, by electrically connecting the element placement unit, in which the light emitting element and the light receiving element are placed to be electrically connected to the light emission-side electrode portion and the light reception-side electrode portion integrally held by the insulating member respectively, to the electric circuits of the circuit board of the smoke detector, so that for example, the light emitting element and the light receiving element can be easily attached to the smoke detector. In addition, by electrically connecting via light emission-side lead portions and light reception-side lead portions, for example, the light emitting element and the light receiving element can be reliably and easily electrically connected to the electric circuits.

### REFERENCE SIGNS LIST

2: light emission-side placement portion
3: light reception-side placement portion
4: holding member
11: outer cover
12: smoke detection unit cover
13: insect net
14: smoke detection unit body
15: element placement unit
16: circuit board
17: light emitting unit
18: light receiving unit
21: light emission-side electrode portion
22: light emission-side holding portion
31: light reception-side electrode portion
32: light reception-side holding portion
41: opening portion for light emission-side leads
42: opening portion for light reception-side leads
43: holding member-side protrusion portion
100: detector
121: labyrinth
122: smoke detection space
141: opening portion for light emitting element
142: opening portion for light receiving element
211: light emission-side lead portion
212: light emission-side connection portion
221: light emission-side support portion
222: light emission-side protrusion portion
223: light emission-side opening portion
311: light reception-side lead portion
312: light reception-side connection portion
313: shield portion
314: shield-side lead portion
315: shield-side connection portion
321: light reception-side support portion
322: light reception-side protrusion portion
323: light reception-side opening portion
400: lead frame
401: fixing portion
900: scattering angle
901: first element angle
902: second element angle
P: intersection point

1. An element placement unit for placing a light emitting element and a light receiving element of a smoke detector that detects smoke by receiving scattered light caused by a scattering of light from the light emitting element by the smoke, using the light receiving element, the unit comprising:
a light emitting element-side electrode portion having conductivity for placing the light emitting element while electrically connecting the light emitting element; and
a light receiving element-side electrode portion having conductivity for placing the light receiving element while electrically connecting the light receiving element,
wherein the light emitting element-side electrode portion and the light receiving element-side electrode portion are integrally formed on a common frame body.

2. The element placement unit according to claim 1,
wherein the light emitting element-side electrode portion and the light receiving element-side electrode portion are disposed to correspond to a first element angle forming a scattering angle represented by an intersection angle between a light emitting axis of the light emitting element and a light receiving axis of the light receiving element.

3. The element placement unit according to claim 1,
wherein a shield portion functioning as an electromagnetic shield for the light receiving element is formed integrally with the light emitting element-side electrode portion and the light receiving element-side electrode portion on the common frame body.

4. The element placement unit according to claim 3,
wherein the shield portion is formed by extending from a part of the light receiving element-side electrode portion.

5. The element placement unit according to claim 1, further comprising:
an insulating member that holds the light emitting element-side electrode portion and the light receiving element-side electrode portion.

6. The element placement unit according to claim 1,
wherein the element placement unit includes a plurality of sets of at least one of the light emitting element-side electrode portions and the light receiving element-side electrode portions.

7. The element placement unit according to claim 1,
wherein the light emitting element-side electrode portion and the light receiving element-side electrode portion include lead portions, and
the light emitting element and the light receiving element of the element placement unit are electrically connected to electric circuits of a circuit board of the smoke detector via the lead portions.

8. The element placement unit according to claim 1,
wherein a shield portion functioning as an electromagnetic shield for the light receiving element is formed integrally with the light emitting element-side electrode portion and the light receiving element-side electrode portion on the common frame body, and
the shield portion is electrically connected to an electric circuit ground of a circuit board of the smoke detector.

9. A method for manufacturing an electrode portion in an element placement unit for placing a light emitting element and a light receiving element of a smoke detector that detects smoke by receiving scattered light caused by a scattering of light from the light emitting element by the smoke, using the light receiving element, the method comprising:
a step of integrally forming a light emitting element-side electrode portion having conductivity on a common frame body, the light emitting element-side electrode portion for placing the light emitting element while electrically connecting the light emitting element; and
a step of integrally forming a light receiving element-side electrode portion having conductivity on the common frame body, the light receiving element-side electrode portion for placing the light receiving element while electrically connecting the light receiving element.

10. A method for manufacturing an electrode portion in an element placement unit for placing a light emitting element and a light receiving element of a smoke detector that detects smoke by receiving scattered light caused by a scattering of light from the light emitting element by the smoke, using the light receiving element, the method comprising:
a step of integrally forming a light emitting element-side electrode portion having conductivity on a common frame body, the light emitting element-side electrode portion for placing the light emitting element while electrically connecting the light emitting element; and
a step of integrally forming a light receiving element-side electrode portion having conductivity on the common frame body, the light receiving element-side electrode portion for placing the light receiving element while electrically connecting the light receiving element,
wherein the light emitting element-side electrode portion and the light receiving element-side electrode portion are disposed to correspond to a first element angle forming a scattering angle represented by an intersection angle between a light emitting axis of the light emitting element and a light receiving axis of the light receiving element.

11. A method for manufacturing an electrode portion in an element placement unit for placing a light emitting element and a light receiving element of a smoke detector that detects smoke by receiving scattered light caused by a scattering of light from the light emitting element by the smoke, using the light receiving element, the element placement unit including a light emitting element-side electrode portion having conductivity for placing the light emitting element while electrically connecting the light emitting element and a light receiving element-side electrode portion having conductivity for placing the light receiving element while electrically connecting the light receiving element, and the light emitting element-side electrode portion and the light receiving element-side electrode portion being integrally formed on a common frame body, the method comprising:
a step of forming a shield portion integrally with the light emitting element-side electrode portion and the light receiving element-side electrode portion on the common frame body, the shield portion functioning as an electromagnetic shield for the light receiving element.

12. The method for manufacturing an electrode portion according to claim 9, further comprising:
a step of holding the light emitting element-side electrode portion and the light receiving element-side electrode portion in the common frame body using a common insulating member; and
a step of separating the light emitting element-side electrode portion, the light receiving element-side electrode portion, and the common insulating member from the common frame body.

13. The method for manufacturing an electrode portion according to claim 12, further comprising:
a step of bending the light emitting element-side electrode portion or the light receiving element-side electrode portion according to a scattering angle represented by an intersection angle between a light emitting axis of the light emitting element and a light receiving axis of the light receiving element.

14. A method for manufacturing a smoke detector that detects smoke by receiving scattered light caused by a scattering of light from a light emitting element by the smoke, using a light receiving element, the method comprising:
a step of electrically connecting an element placement unit, in which a light emitting element and a light receiving element are disposed to correspond to a first element angle forming a scattering angle represented by an intersection angle between a light emitting axis of the light emitting element and a light receiving axis of the light receiving element and in which the light emitting element and the light receiving element are placed to be electrically connected to the light emission-side electrode portion and the light reception-side electrode portion integrally held by an insulating member respectively, to an electric circuit of a circuit board of the smoke detector via a lead portion of each of the light emitting element-side electrode portion and the light receiving element-side electrode portion.
